(19) United States
(12) Patent Application Publication
(10) Pub. No.: US 2022/0216176 A1
(43) Pub. Date: Jul. 7, 2022

(54) Semiconductor Assembly Packaging Method, Semiconductor Assembly and Electronic Device

(71) Applicant: Yibu Semiconductor Co., Ltd., Shanghai (CN)

(72) Inventor: Weiping LI, Shanghai (CN)

(21) Appl. No.: 17/568,293

(22) Filed: Jan. 4, 2022

(30) Foreign Application Priority Data
Jan. 4, 2021 (CN) 202110002410.X

(51) Int. Cl. H01L 23/00

(52) U.S. Cl. CPC H01L 24/81; H01L 24/16; H01L 2224/10165; H01L 2224/10135; H01L 2224/81141; H01L 2224/16238; H01L 2224/81203; H01L 2224/81091; H01L 2224/81986; H01L 2224/16227

(57) ABSTRACT

A semiconductor assembly packaging method, a semiconductor assembly and an electronic device are provided. The method comprises providing an interconnect board and at least one semiconductor device; aligning and attaching the at least one semiconductor device to the interconnect board by forming a plurality of alignment solder joints; applying pressure to the at least one semiconductor device and/or the interconnect board while the alignment solder joints are in a molten or partially molten state, whereby first connection terminals on the interconnect board are joined with and bonded to corresponding second connection terminals on the at least one semiconductor device. Using the packaging method, the semiconductor device and the interconnect board can be aligned accurately using relatively simple and low cost processes and equipment. The method can also be used to align and bond at least one semiconductor device to another semiconductor device.

### CROSS REFERENCE TO RELATED APPLICATIONS

This application claims the benefit of priority under the Paris Convention to Chinese Patent Application No. CN202110002410.X, filed Jan. 4, 2021, entitled “Semiconductor Assembly Packaging Method, Semiconductor Assembly and Electronic Device,” which is incorporated by reference herein in its entirety. This application is related to co-pending U.S. patent application Ser. No. 17/535,983, entitled “Semiconductor Packaging Method, Semiconductor Assembly and Electronic Device Comprising Semiconductor Assembly,” filed Nov. 26, 2021, U.S. patent application Ser. No. 17/535,986, entitled “Semiconductor Packaging Method, Semiconductor Assembly and Electronic Device Comprising Semiconductor Assembly,” filed Nov. 26, 2021, U.S. patent application Ser. No. 17/562,936, entitled “Semiconductor Packaging Method, Semiconductor Assembly and Electronic Device Comprising Semiconductor Assembly,” filed Dec. 27, 2021, and U.S. patent application Ser. No. 17/562,939, entitled “Semiconductor Packaging Method, Semiconductor Assembly and Electronic Device Comprising Semiconductor Assembly,” filed Dec. 27, 2021, each of which is incorporated by reference herein in its entirety.

### FIELD OF THE INVENTION

The present application relates to the technical field of semiconductor manufacturing, in particular to a semiconductor assembly packaging method, a semiconductor assembly and electronic device.

### BACKGROUND

In the manufacture of microelectronic products, a semiconductor device (e.g., one or more packaged chips or dies) is usually soldered on an interconnect board (e.g., a substrate or an interposer) to obtain a semiconductor assembly, and the semiconductor assembly is then interconnected with other components to form an electronic product or system.

In other scenarios, it may be desirable to solder one or more semiconductor devices to another semiconductor device to achieve interconnection between the semiconductor devices.

A technical problem to be solved urgently relates to how to realize high-precision placement and fixation of a semiconductor device on an interconnect board or another semiconductor device with lower equipment and process cost.

### SUMMARY

To solve the above technical problems, a method of packaging a semiconductor assembly is provided herein. In some embodiments, a method of packaging a semiconductor assembly comprises providing an interconnect board and at least one semiconductor device. In some embodiments, a plurality of first connecting terminals and a plurality of first alignment solder parts are formed on the interconnect board, a plurality of second connecting terminals and a plurality of second alignment solder parts are formed on the active surface of each semiconductor device, the first connecting terminals and the second connecting terminals are in one-to-one correspondence, the first alignment solder parts and the second alignment solder parts are in one-to-one correspondence, and the height sum of any first connecting terminal and its corresponding second connecting terminal is smaller than the height sum of any first alignment solder part and its corresponding second alignment solder part.

In some embodiments, the method further comprises placing the at least one semiconductor device on the interconnect board such that the first alignment solder part is substantially or approximately aligned with a corresponding second alignment solder part; and bonding the first alignment solder parts and the corresponding second alignment solder parts into alignment solder joints in a molten or partially molten state by adopting a soldering process so as to more accurately align the at least one semiconductor device. In some embodiments, a space is reserved between the first connecting terminals and the corresponding second connecting terminals.

In some embodiments, the method further comprises applying pressure to the at least one semiconductor device toward the interconnect board while the alignment solder joints are melted or partially melted and the first connection terminal and/or the second connection terminal are in a melted or partially melted state, so that each first connection terminal and its corresponding second connection terminal are bonded to each other into a corresponding interconnection bond in a melted or partially melted state; and releasing the pressure on the at least one semiconductor device after the alignment solder joints and/or the interconnection bonds are solidified or substantially solidified.

In some embodiments, a method of packaging a semiconductor assembly comprises providing a first semiconductor device and at least one second semiconductor device. In some embodiments, a plurality of first connecting terminals and a plurality of first alignment solder parts are formed on the active surface of the first semiconductor device, a plurality of second connecting terminals and a plurality of second alignment solder parts are formed on the active surface of the at least one second semiconductor device, the first connecting terminals and the second connecting terminals are in one-to-one correspondence, the first alignment solder parts and the second alignment solder parts are in one-to-one correspondence, and the height sum of any first connecting terminal and its corresponding second connecting terminal is smaller than the height sum of any first alignment solder part and its corresponding second alignment solder part.

In some embodiments, the method further comprises placing the at least one second semiconductor device on the first semiconductor device such that the first alignment solder part is substantially (or approximately) aligned with a corresponding second alignment solder part; and bonding the first alignment solder parts and the corresponding second alignment solder parts into alignment solder joints in a molten or partially molten state by using a soldering process so as to precisely or more precisely align the first semiconductor device and the at least one second semiconductor device, leaving a space between the first connection terminals and the corresponding second connection terminals.

In some embodiments, the method further comprises applying pressure to the at least one second semiconductor device toward the first semiconductor device while the alignment solder joints are melted or partially melted and the first connection terminal and/or the second connection terminal are in a melted or partially melted state, so that each first connection terminal and its corresponding second connection terminal are bonded to each other into a corresponding interconnection bond in a melted or partially melted state; and releasing the pressure on the at least one semiconductor device after the alignment solder joints and/or the interconnection bonds are solidified or substantially solidified.

In some embodiments, a method of packaging a semiconductor assembly comprises providing an interconnect board and at least one semiconductor device. In some embodiments, a plurality of first connecting terminals and a plurality of first alignment solder parts are formed on the interconnect board, a plurality of second connecting terminals and a plurality of second alignment solder parts are formed on the active surface of each semiconductor device, the first connecting terminals and the second connecting terminals are in one-to-one correspondence, the first alignment solder parts and the second alignment solder parts are in one-to-one correspondence, and the height sum of any first connecting terminal and its corresponding second connecting terminal is smaller than the height sum of any first alignment solder part and its corresponding second alignment solder part.

In some embodiments, the method further comprises placing the at least one semiconductor device on the interconnect board such that each first alignment solder part is substantially (or approximately) aligned with a corresponding second alignment solder part; and bonding the first alignment solder parts and the corresponding second alignment solder parts into alignment solder joints in a molten or partially molten state by adopting a soldering process so as to more accurately align the at least one semiconductor device. In some embodiments, a space is reserved between the first connecting terminals and the corresponding second connecting terminals.

In some embodiments, the method further comprises applying pressure to the at least one semiconductor device toward the interconnect board while the alignment solder joints are melted or partially melted so that the first connection terminals and the corresponding second connection terminals are bonded into interconnection bonds through thermocompression bonding.

In some embodiments, a method of packaging a semiconductor assembly comprises providing a first semiconductor device and at least one second semiconductor device. In some embodiments, a plurality of first connecting terminals and a plurality of first alignment solder parts are formed on the active surface of the first semiconductor device, a plurality of second connecting terminals and a plurality of second alignment solder parts are formed on the active surface of the at least one second semiconductor device, the first connecting terminals and the second connecting terminals are in one-to-one correspondence, the first alignment solder parts and the second alignment solder parts are in one-to-one correspondence, and the height sum of any first connecting terminal and its corresponding second connecting terminal is smaller than the height sum of any first alignment solder part and its corresponding second alignment solder part.

In some embodiments, the method further comprises placing the at least one second semiconductor device on the first semiconductor device such that the first alignment solder parts is substantially (or approximately) aligned with a corresponding second alignment solder parts; and bonding the first alignment solder parts and the corresponding second alignment solder parts into alignment solder joints in a molten or partially molten state by using a soldering process so as to precisely or more precisely align the first semiconductor device and the at least one second semiconductor device with a space left between the first connection terminal and the corresponding second connection terminal.

In some embodiments, when the alignment solder joints are melted or partially melted, the at least one second semiconductor device is pressed towards the first semiconductor device, so that the first connecting terminals and the corresponding second connecting terminals are bonded into the interconnection bonds through thermocompression bonding.

In some embodiments, a semiconductor assembly manufactured by a method provided herein can be a semiconductor component or an electronic device comprising the semiconductor component.

Compared with existing technologies, the embodiments described herein take advantage of the minimum surface energy principle and allow molten and partially molten solder joints automatically introducing the semiconductor device to the target location to achieve surface energy minimization. Thus, the alignment solder joints allow the semiconductor device to be securely and accurately fixed at the target location after solidification and substantial solidification thereof. By optimizing the design for the first and second alignment solder parts (e.g., for aspects of volume, geometry, composition, location, distribution, and quantity, etc.), the most accurate, efficient, and reliable self-alignment capability can be achieved. The accurate alignment of the semiconductor device also ensures the accurate alignment of the first connection terminals and the second connection terminals. A certain degree of placement deviation is allowed when picking up and placing the semiconductor device in view of the self-alignment capability of the alignment solder joints, so that the requirement on the placement accuracy of the semiconductor device can be significantly reduced, and the speed of the semiconductor device picking-up and placing operations can be significantly increased, thereby improving the efficiency, and reducing process and equipment costs.

### BRIEF DESCRIPTION OF THE DRAWINGS

FIGS. 1a-1d are schematic flow charts of several packaging methods according to some embodiments.

FIGS. 2-8 are cross-sectional views schematically illustrating various stages of a semiconductor assembly packaging method according to some embodiments.

FIG. 9 includes a front view of a portion of an interconnect board and cross-section view along a line AA in the front view according to some embodiments.

FIG. 10 includes a front view of a portion of an interconnect board and cross-section view along a line BB in the front view according to some embodiments.

### DETAILED DESCRIPTION OF THE EMBODIMENTS

In the present application, the terms such as “including” or “having,” or the like, are intended to indicate the presence of the disclosed features, integers, steps, acts, components, parts, or combinations thereof, but do not preclude the presence or addition of one or more other features, integers, steps, acts, components, parts, or combinations thereof.

Certain embodiments or certain features of various embodiments may be combined with each other without conflict. Examples of embodiments will be described in detail below with reference to the attached drawings.

Semiconductor devices are core components of modern electronic devices or products. As used herein, the term “semiconductor device” may refer to a chip (also interchangeably referred to as die, integrated circuit) produced by a chip factory (fab), i.e., a chip that has not been packaged after wafer dicing and testing, and which may typically have only interconnect pads for external connection. The semiconductor device may also be a pre-processed (at least partially packaged) chip, such as with interconnect bumps (bump) formed on the interconnect pads, or may have additional structures, such as stacked chips and packaged chips, as desired. Semiconductor devices may also include discrete semiconductor devices and multi-chip semiconductor devices. Discrete semiconductor devices include, for example, single digital logic processors, transistors, bipolar transistors, field effect transistors, active devices such as integrated circuits, and passive devices such as diodes, chip resistors, capacitors, inductors, and Integrated Passive Devices (IPDs). Multi-chip semiconductor devices, such as a module of a image sensor (CIS) and an image processor (ASIC), a Central Processing Unit (CPU), and a dynamic memory (DRAM). A semiconductor device according to the present application may be in a packaged state or may be in a bare chip state.

Some embodiments include technical solutions on how to solder a semiconductor device to an interconnect board to achieve interconnection of signals between the semiconductor device and the interconnect board and/or how to solder the semiconductor device to another semiconductor device.

The term “active surface” as used herein generally refers to a surface on a front (or active) side of a semiconductor device having a circuit function, including interconnect pads (or interconnect bumps formed on the interconnect pads) thereon, and may also be interchangeably referred to as a front surface or a functional surface. A surface having no circuit function on an opposing back side of the semiconductor device may be interchangeably referred to as a passive surface or a back surface.

The term “connection terminal” as used herein generally refers to an interconnect pad or an interconnect bump on the active surface of a semiconductor device.

The term “alignment solder part” as used herein generally refers to a structure that may be aligned and soldered to a corresponding other alignment solder part for alignment by soldering methods known in the art.

Examples of embodiments are described further below with reference to the drawings.

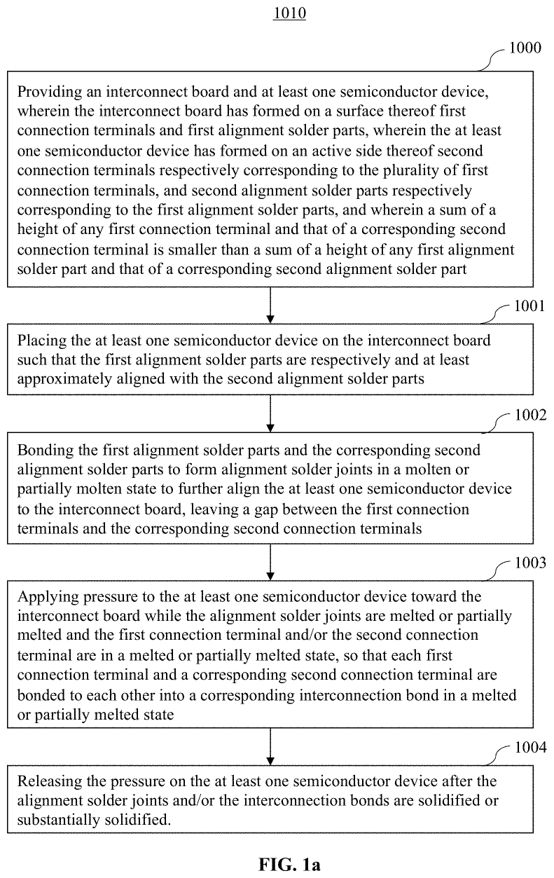

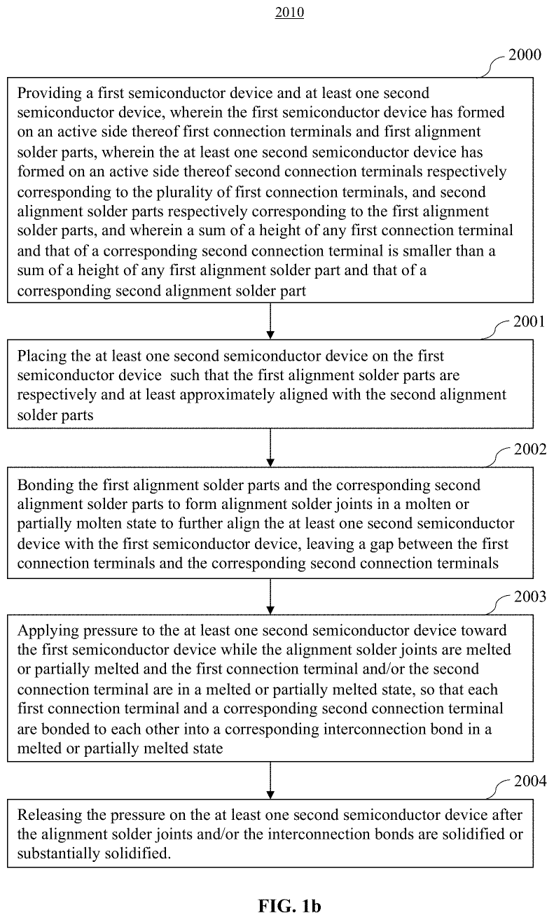

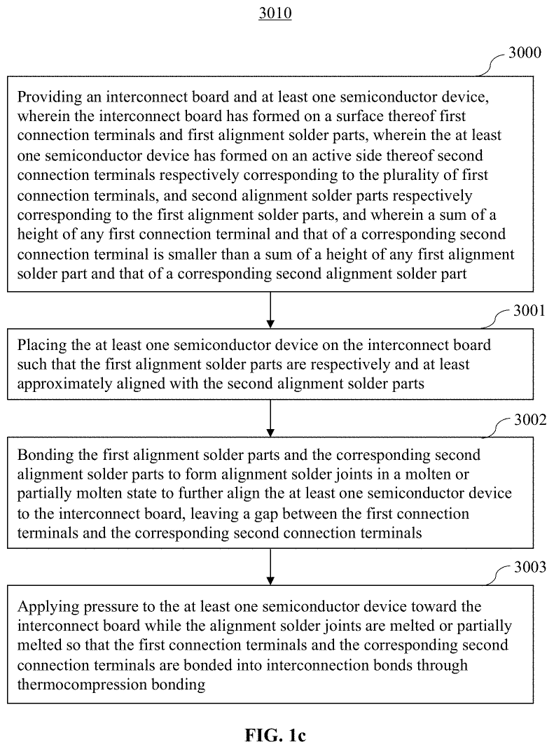

As shown in FIG. 1a, a semiconductor assembly packaging method 1010 according to some embodiments includes steps 1000-1004, as described below.

Step 1000—providing an interconnect board and at least one semiconductor device.

In some embodiments, a plurality of first connection terminals and a plurality of first alignment solder parts are formed on the interconnect board, any one of the plurality of second connection terminals and a plurality of second alignment solder parts are formed on an active surface of the semiconductor device, the first connection terminals and the second connection terminals are in one-to-one correspondence, the first alignment solder parts and the second alignment solder parts are in one-to-one correspondence, and a sum of a height of any first connection terminal and that of a corresponding second connection terminals is smaller than a sum of a height of any one of the first alignment solder parts and that of a corresponding one of the second alignment solder parts.

In some embodiments, the at least one semiconductor device includes a plurality of semiconductor devices, which may include semiconductor devices that are different from each other at least in part in function, size, or shape, or may be the same as each other.

The material of the interconnect board is not limited in this application, for example, the material of the interconnect board may be silicon, organic polymer, glass, ceramic or metal, or a combination of the above materials. In some embodiments, the interconnect board is also referred to as a substrate. In other embodiments, the interconnect board is also referred to as an interposer. The interconnect board can be any board material that can be used for receiving the at least one semiconductor device and realizing signal interconnection with the at least one semiconductor device.

In some embodiments, either one of a first alignment solder part and a second alignment solder part is an alignment solder bump and the other is an alignment pad corresponding to the alignment solder bump. In other embodiments, the first alignment solder part and the second alignment solder part are both alignment solder bumps, and the melting points of the first alignment solder part and the second alignment solder part can be the same or different.

The solder bumps are made of solder, for example, and the alignment solder joints are formed by melting the solder in a subsequent step.

By way of example, alignment solder bumps may be pre-fabricated on a semiconductor device (e.g., a wafer) or a carrier using a bumping process (e.g., electroplating, ball-planting, stencil printing, evaporation/sputtering, etc.) known in the art. As an example, alignment pads may be fabricated on the semiconductor device or the carrier board in advance using a deposition (e.g., metal layer) -photolithography-etching process. Any other solder configuration or form may be used as long as the first and second alignment solder parts are capable of being soldered to each other for alignment purposes.

In some embodiments, the first alignment solder and the second alignment solder correspond to each other in volume, size, geometry, composition, distribution, location, and number, so that the semiconductor devices can be precisely aligned to the respective target positions on the carrier board by soldering to each other.

In some embodiments, the first connection terminals are solder bumps, and the second connection terminals parts are solder pads corresponding to the solder bump. Or, the second connection terminals are solder bumps, and the first connection terminals are solder pads corresponding to the solder bump. Or, the first connection terminals and the second connection terminals are both solder bumps.

The solder bumps are made of solder, for example, and the interconnection bonds are formed by melting the solder in a subsequent step.

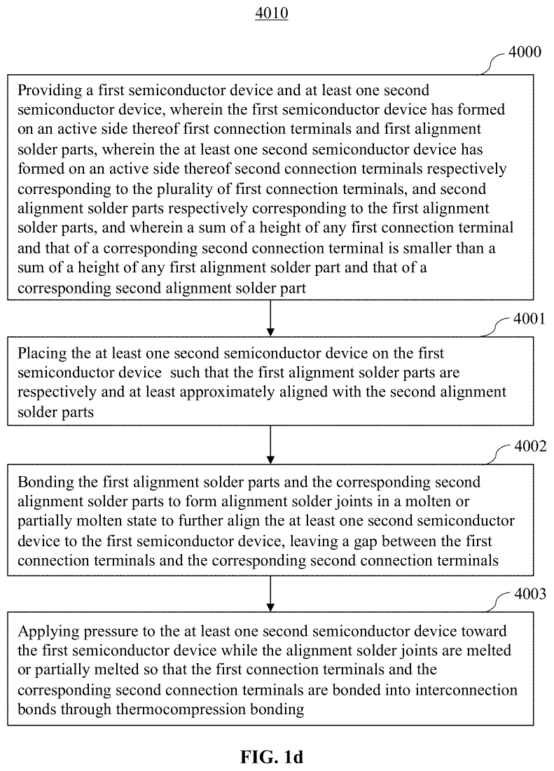

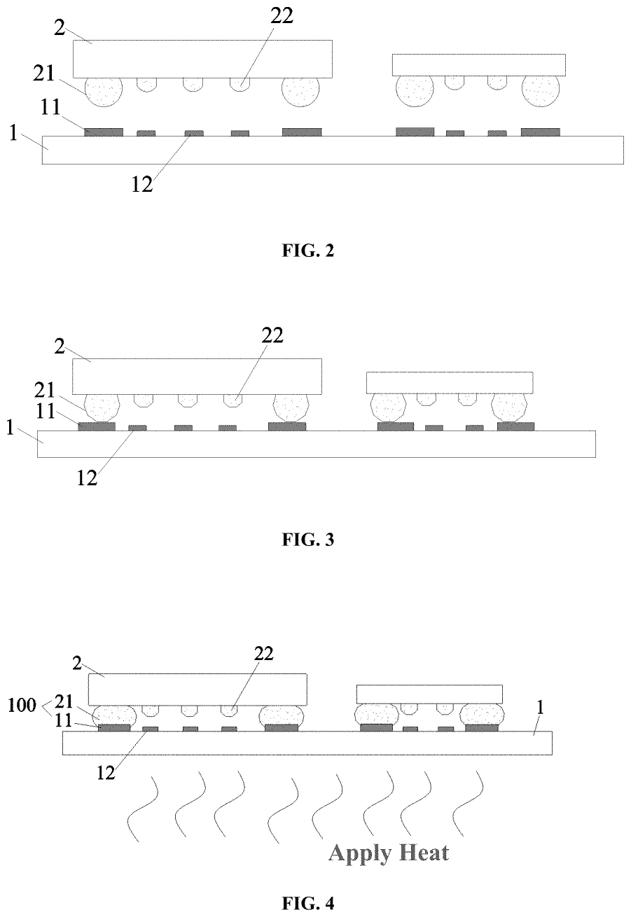

Referring to FIG. 2, a plurality of first alignment solder parts 11 and a plurality of first connection terminals 12 are formed on an upper surface of the interconnect board 1. Two semiconductor devices 2 are provided in step 1000, the two being of different sizes. A plurality of second alignment lands 21 and a plurality of second connection terminals are formed on the active surface of each semiconductor device 2.

There may be interconnecting leads between the first connection terminals on the interconnect board or there may be no interconnecting leads between each other. If the surface of the interconnect board having the first alignment solder parts is referred to as “front surface” of the interconnect board, and the surface of the interconnect board opposite to the “front surface” thereof is referred to as “back surface” of the interconnect board, the terminals for interconnecting the finally manufactured semiconductor package with external signals may be provided on the “back surface” of the interconnect board, or may be provided on the “front surface” of the interconnect board.

Step 1001—placing the at least one semiconductor device on the interconnect board such that each first alignment solder part is substantially (or approximately) aligned with a corresponding second alignment solder part.

In some embodiments, “substantial alignment” or “approximate alignment” may mean that the first alignment solder parts and the corresponding second alignment solder parts are respectively in contact with each other, respectively, without being precisely centered in a direction perpendicular to the passive surface. Here, “centered” is generally meant that the centers of the first and second alignment solder parts are aligned in a direction perpendicular to the active or passive surface. In some embodiments, “substantial alignment” of the first alignment solder parts with the second alignment solder parts means that there is at least contact between the first alignment solder parts and the second alignment solder parts to the extent that self-alignment is possible by virtue of the principle of minimum surface energy of the alignment solder joint in a molten or partially molten state during soldering, as described below, and thus “substantial alignment” includes a state of imprecise alignment but at least physical contact, but may not exclude a state of exact alignment.

Referring to FIG. 3, when the at least one semiconductor device 2 is placed on the interconnect board 1 in step 1001, the active surface of the at least one semiconductor device 2 faces the interconnect board 1 (i.e., the surface on which the first alignment solder 11 is formed), and the passive surface of the at least one semiconductor device 2 faces away from the interconnect board 1. In this step, the at least one semiconductor device 2 and the interconnect board 1 do not require perfect alignment.

Step 1002—bonding the first alignment solder parts and the corresponding second alignment solder parts to each other to form alignment solder joints in a molten or partially molten state by using a bonding process to align precisely or more precisely the at least one semiconductor device. In some embodiments, a space is left between the first connection terminal and the corresponding second connection terminal.

In some embodiments, “precise alignment” indicates a state where a deviation between an actual position and a target position of a semiconductor device on the carrier board is within a preset tolerance in the art. In some embodiments, precise alignment is achieved using the principle of minimum surface energy exhibited by the solder joint or bonds formed by soldering the first and second alignment solder parts in a molten or partially molten state during soldering. In particular, when the first alignment solder parts and the second alignment solder parts are in contact with each other but are not precisely centered in a direction perpendicular to the active surface of the semiconductor device or the carrier board, in the soldering process, one of a first alignment solder part and a corresponding second alignment solder part which is an alignment solder bump is melted or partially melted and wets the other one which is an alignment solder pad or another alignment solder bump, or both the first and second alignment solder parts melt or partially melt as alignment solder part bumps, thereby forming an alignment solder part in a molten or partially molten state In some embodiments, the alignment solder part in the molten or partially molten state tends to move in a deformation based on a minimum surface energy principle to bring the first alignment solder part and the second alignment solder part closer to a centered state, thereby driving the semiconductor device which is lighter relative to the carrier board to be accurately aligned to the target position on the carrier board.

In some embodiments, after the first alignment solder parts and the second alignment solder parts are bonded, the active surface of the semiconductor device and the interconnect board are spaced apart to form a space therebetween due to the height of the alignment solder parts (in a direction perpendicular to the active surface of the semiconductor device or the interconnect board) formed thereby. It should be ensured that a space is left between the first connection terminal and the corresponding second connection terminal.

The first and second connection terminals may have a melting point higher than or lower than a temperature at which the first and second alignment solder parts are combined into the alignment solder joint. When each first alignment solder part and a corresponding second alignment solder part are fused together, the first connection terminals and/or the second connection terminals may be in a solid state or may be in a molten state. Since the first connection terminals and the second connection terminals are separated from each other at this time, they are not bonded together to form an interconnection bond.

In some embodiments, the alignment solder bump is made of solder, and the soldering may be performed by various means known in the art for melting solder, including but not limited to reflow soldering, laser soldering, high frequency soldering, infrared soldering, and the like.

Referring to FIG. 4, each first alignment solder part 11 is in the form of a pad, and each second alignment solder part 21 is in the form of a bonding bump. When a second alignment solder part 21 is in a molten state and wets a corresponding first alignment solder part 11, the second alignment solder part 21 tends to move to the center of the first alignment solder part 11 under the action of the minimum surface energy. As a result, the semiconductor device 2 is driven to move to the target or expected position. Each first alignment solder part 11 and a corresponding second alignment solder part 21 are combined into the alignment solder joints 100. In this way, the self-alignment between the interconnect board 1 and the semiconductor device 2 is completed.

Comparing FIGS. 4 and 3, the semiconductor device 2 is automatically moved to a position accurately aligned with the interconnect board 1 during the soldering process.

Step 1003—applying pressure to the at least one semiconductor device towards the interconnect board while the alignment solder joints are melted or partially melted and the first connection terminal and/or the second connection terminal are in a melted or partially melted state, so that the first connection terminal and the corresponding second connection terminal are bonded to each other into an interconnection bond in a melted or partially melted state.

Since the position of the semiconductor device is the expected position of the semiconductor device, the first connecting terminal and the second connecting terminal are opposite, and the semiconductor device is pressed downwards, the first connecting terminal and the second connecting terminal can be combined in a centered state to form an interconnection bond, so that good electrical connection is realized.

In some embodiments, after the alignment solder joints are solidified or basically solidified, the alignment solder joints are melted or partially melted again by adopting the soldering process, and the first connecting terminal and/or the second connecting terminal are/is in a molten or partially molten state, and then the at least one semiconductor device is pressed.

Another embodiment is: after the alignment solder joints in the molten or partially molten state is formed, the alignment solder joints are kept in the molten or partially molten state, and the first connection terminal and/or the second connection terminal are/is in the molten or partially molten state, and the at least one semiconductor device is pressed towards the interconnect board.

The former is advantageous for inspecting the alignment state of the semiconductor device, and the latter is advantageous for improving the production efficiency.

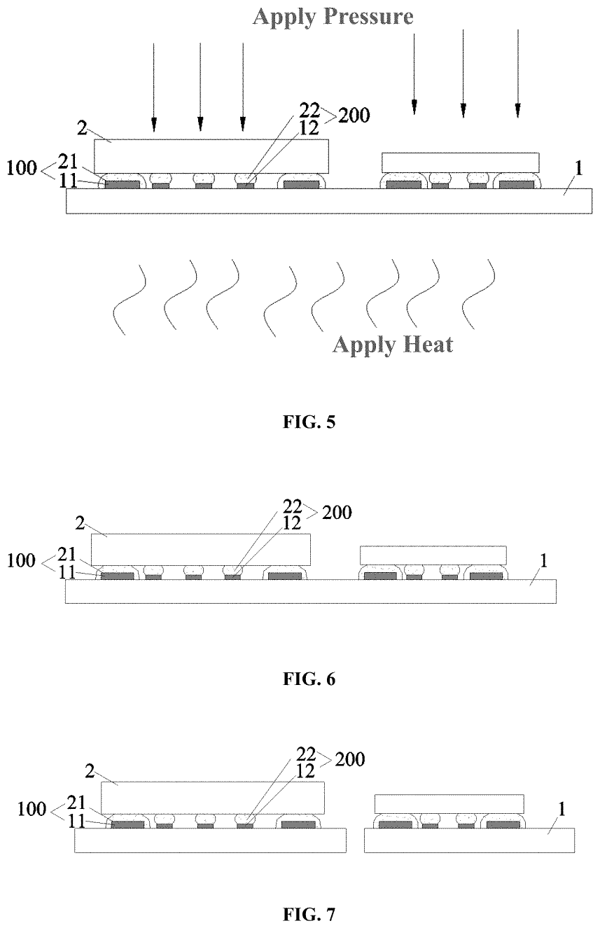

Referring to FIG. 5, the alignment solder joints 100 are flattened so that each first connection terminal 12 and the corresponding second connection terminal 22 are combined into an interconnection bond 200.

In some embodiments, the at least one semiconductor device may be pressed down using a platen.

During the interval between step 1002 and step 1003, a process of checking the soldering state of the alignment solder joints may be performed.

Step 1004—releasing the press on the at least one semiconductor device after the alignment solder joints and/or the interconnection bonds are solidified or substantially solidified.

The premise for releasing the pressure on the at least one semiconductor device is that the shapes of the alignment solder joints and the interconnection bonds can be kept stable, and the parameters such as the time, the acting force, the pressing distance, the pressing time and the like for releasing the pressure on the at least one semiconductor device can be flexibly adjusted by a person skilled in the art according to the actual situation.

Referring to FIG. 6, after the soldering is completed, the alignment solder joints 100 and the interconnection bonds 200 are located at desired positions.

The semiconductor device is automatically precisely introduced to the target position based on the principle of minimum surface energy to achieve surface energy minimization, and the solder joints are aligned so that the semiconductor device is firmly and accurately fixed at the target position. Such as optimizing the design for the first and second alignment solder parts (e.g., for aspects of volume, geometry, composition, location, distribution, and quantity, etc.), the most accurate, efficient, and reliable self-alignment capability can be achieved. The accurate alignment of the semiconductor device also ensures the accurate alignment of each first connection terminal 12 and the corresponding second connection terminal 22. A certain degree of placement deviation is allowed when picking up and placing the semiconductor device in view of the self-alignment capability of the alignment solder joints, so that the requirement on the placement accuracy of the semiconductor device can be significantly reduced, and the speed of the semiconductor device picking-up and placing operation can be significantly increased, thereby improving the process efficiency and reducing the process and equipment costs.

Referring to FIG. 6, in some embodiments, the plurality of second alignment parts 21 are located outside an area where the second connection terminals 22 are located on the active surface. Of course, the second alignment solder parts 21 may be provided in the area where the second connection terminals 22 are. The skilled person can flexibly set the position of the second alignment solder parts 21 according to practical situations.

In some embodiments, the perimeters of the first alignment solder of the interconnect board are each pre-formed with a solder well. When the semiconductor device is pressed down, the material of the alignment solder j ointsin a molten or partially molten state may overflow or flow to the periphery, easily causing a short circuit between an alignment solder joint and an interconnection bond or between an alignment solder joint and another alignment solder joint or causing other adverse effects. The solder wells are used to receive the excess material of the alignment solder joints.

Referring to FIG. 9, in some embodiments, the interconnect board 1 has a groove 13 formed therein around the first alignment solder part 11, the groove 13 for receiving material of the alignment solder part 100 in a molten state. That is, the solder well is recessed.

In step 1003, as the at least one semiconductor device is pressed down toward the interconnect board, the material forming the alignment solder joints 100 may overflow or flow outward, which may easily cause a short circuit between an alignment solder joint and an interconnection bond. To avoid this problem, a groove may be provided around the first alignment solder part for receiving the material of the overflow alignment solder part in a molten state.

In some embodiments, the groove surrounds the first alignment solder part, which means that an orthographic projection of the groove on the plane of the interconnect board surrounds an orthographic projection of the first alignment solder part on the plane of the interconnect board.

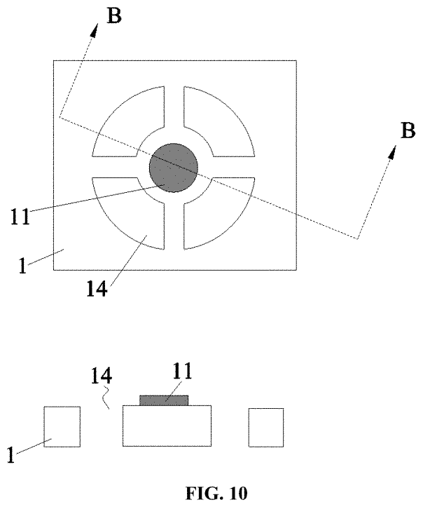

In some embodiments, referring to FIG. 10, the interconnect board 1 is formed with a through hole 14 surrounding the first alignment solder 11, and the through hole 14 is used for the material of the alignment solder 100 in a molten state to flow out of the interconnect board , i.e. the solder wells are through-hole shaped.

Unlike the previous embodiment, the interconnect board does not retain excess alignment solder joint material, but rather, when the excess alignment solder joint material is in a molten state and spills around, the excess alignment solder joint material flows directly out of the interconnect board through the via.

In some embodiments, the through holes are multiple and spaced from each other. The design is to ensure the mechanical strength of the interconnect board.

In some embodiments, the entire interconnect board is provided as a separate product (i.e., a semiconductor assembly as described herein) after the soldering process for each semiconductor device is completed.

In other embodiments, to improve production efficiency, the interconnect board is large enough that after the soldering process of each semiconductor device is completed, the interconnect board needs to be diced to obtain a plurality of semiconductor assemblies.

That is, after the at least one semiconductor device is accurately fixed on the interconnect board, the method further comprises dicing the interconnect board to obtain a plurality of semiconductor assemblies. In some embodiments, any semiconductor assembly corresponds to at least one semiconductor device.

In some embodiments, referring to FIG. 7, alignment solder joints 100 are retained, which may serve the function of connecting electrical signals, power supply potential, for grounding, or for mechanical attachment and heat dissipation, among other functions.

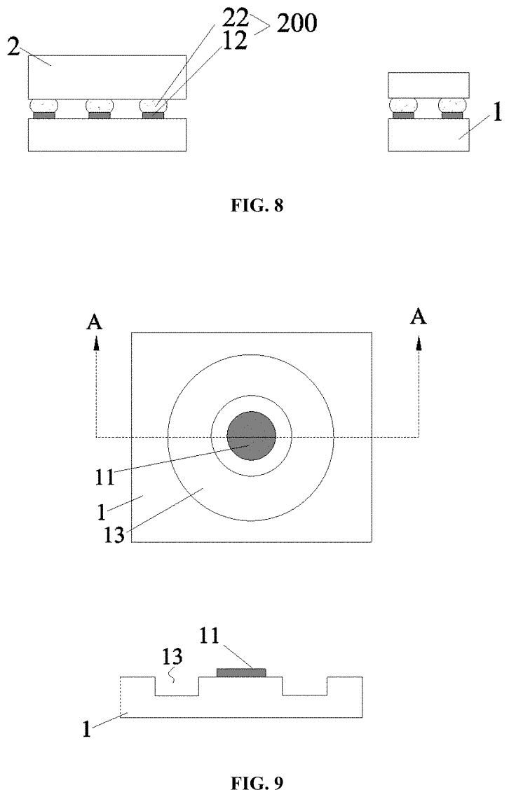

In some embodiments, referring to FIG. 8, when the substrate 1 is diced, at least one alignment solder joint 100 is also cut off

And when an alignment solder joint 100 does not need to be left, as shown in FIG. 8, the alignment solder joints 100 may be cut off when the interconnect board 1 is diced.

Referring to FIG. 1b, a semiconductor assembly packaging method 2010 is illustrated according to some embodiments. The method 2010 and the packaging method 1010 described above include similar inventive concept, and the corresponding parts in the method 1010 are not described again. The method 2010 comprises the steps 2000-2004, as described below.

Step 2000—providing a first semiconductor device and at least one second semiconductor device. In some embodiments, a plurality of first connection terminals and a plurality of first alignment solder parts are formed on an active surface of the first semiconductor device, a plurality of second connection terminals and a plurality of second alignment solder parts are formed on an active surface of the at least one second semiconductor device, the first connection terminals and the second connection terminals are in one-to-one correspondence, the first alignment solder parts and the second alignment solder parts are in one-to-one correspondence, and the height sum of any first connection terminal and corresponding second connection terminal is smaller than the height sum of any first alignment solder part and corresponding second alignment solder part.

Step 2001—placing the at least one second semiconductor device on the first semiconductor device such that the first alignment solder part is substantially (or approximately) aligned with the corresponding second alignment solder part.

Step 2002—bonding the first alignment solder part and the corresponding second alignment solder part to each other to form an alignment solder joint in a molten or partially molten state using a bonding process to align the first semiconductor device precisely or more precisely and the at least one second semiconductor device with a space left between the first connection terminal and the corresponding second connection terminal.

Step 2003—applying pressure to the at least one second semiconductor device toward the first semiconductor device while the alignment solder joints are melted or partially melted and the first connection terminal and/or the second connection terminal are in a melted or partially melted state, so that the first connection terminal and the corresponding second connection terminal are bonded to each other into an interconnection bond in a melted or partially melted state.

Step 2004—releasing the pressure on the at least one second semiconductor device after the alignment solder joints and/or the interconnection bonds are solidified or substantially solidified.

The method 2010 differs from the method 1010 shown in FIG. 1a in that: the underlying interconnect board is replaced by a first semiconductor device, i.e. one or more second semiconductor devices are soldered to the first semiconductor device. Thereby enabling direct interconnection of the second semiconductor device with the at least one first semiconductor device. The related technical details can refer to the related description of the method 1010 shown in FIG. 1a, and are not described herein again.

In some embodiments, either one of the first and second alignment solder parts has the form of a solder bump and the other has the form of a pad corresponding to the solder bump; or the first alignment solder part and the second alignment solder part are both in the form of soldering bumps.

In some embodiments, the solder bumps are made of solder and the alignment solder joints are formed by melting the solder.

In some embodiments, either one of each first connection terminal and the corresponding second connection terminal has a form of a soldering bump, and the other has a form of a pad corresponding to the soldering bump; or the first connecting terminal and the second connecting terminal are both in the form of soldering bumps5.

In some embodiments, the solder bumps are made of solder and the interconnection bonds are formed by melting the solder.

In some embodiments, substantially aligning the first alignment solder part with a corresponding second alignment solder part comprises: bringing the first and corresponding second alignment solder parts into contact with each other. In some embodiments, an orthographic projection of centers of the first and corresponding second alignment solder parts on a plane in which an active surface of the first semiconductor device is located allows for deviation.

In some embodiments, the at least one second semiconductor device is pressed with a pressing plate while the at least one second semiconductor device is pressed toward the first semiconductor device.

In some embodiments, applying pressure to the at least one second semiconductor device toward the first semiconductor device while the alignment solder joints are melted or partially melted and the first connection terminal and/or the second connection terminal are in a melted or partially melted state so that each first connection terminal and the corresponding second connection terminal are joined to each other into an interconnection bond in a melted or partially melted state includes: after the alignment solder joints are solidified or basically solidified, the at least one second semiconductor device is pressed after the alignment solder joints are melted or partially melted again by adopting the soldering process and the first connecting terminal and/or the second connecting terminal are/is in a melted or partially melted state.

In some embodiments, applying pressure to the at least one second semiconductor device toward the first semiconductor device while the alignment solder joints are melted or partially melted and the first connection terminal and/or the second connection terminal are in a melted or partially melted state so that the first connection terminal and the corresponding second connection terminal are joined to each other into an interconnection bond in a melted or partially melted state includes: after the alignment solder joints in the molten or partially molten state are formed, the alignment solder joints are kept in the molten or partially molten state, the first connecting terminals and/or the second connecting terminals are/is in the molten or partially molten state, and the at least one second semiconductor device is pressed towards the first semiconductor device.

In some embodiments, referring to FIG. 1c, a semiconductor device packaging method 3010 in accordance with some embodiments includes steps 3000-3003, as described below.

Step 3000—providing an interconnect board and at least one semiconductor device. In some embodiments, a plurality of first connection terminals and a plurality of first alignment solder parts are formed on the interconnect board, and any of the semiconductor device active surface is formed with a plurality of second connection terminals and a plurality of second alignment solder parts, the first connection terminals and the second connection terminals one-to-one, the first alignment solder parts and the second alignment solder parts one-to-one, and any of the first connection terminals and the corresponding second connection terminals have a height less than the height of any of the first alignment solder parts and the corresponding second alignment solder parts.

Step 3001—placing the at least one semiconductor device on the interconnect board such that the first alignment solder part is substantially (or approximately) aligned with a corresponding second alignment solder part.

Step 3002—bonding the first alignment solder part and the corresponding second alignment solder part to each other to form an alignment solder joint in a molten or partially molten state by using a bonding process to align the at least one semiconductor device precisely or more precisely. In some embodiments, a space is left between the first connection terminal and the corresponding second connection terminal.

Step 3003—applying pressure to the at least one semiconductor device towards the interconnect board while the alignment solder bumps are melted or partially melted, so that the first connection terminals and the corresponding second connection terminals are bonded into interconnection bonds through thermocompression bonding.

The method 3010 differs from the method 1010 shown in FIG. 1a in that the interconnection bonds are formed by bonding the first connection terminal and the corresponding second connection terminal through a thermal compression bonding process. Related technical details can refer to the related description of the method 1010 shown in FIG. 1a, and are not described herein again.

In some embodiments, since the mechanical strength of the interconnection bonds is stable enough, when the pressure on the semiconductor device is removed, the alignment solder joints can remain in a solidified state or in a molten state, and those skilled in the art can flexibly adjust the alignment solder joints according to actual situations.

In some embodiments, either one of the first and second alignment solder parts has the form of a solder bump and the other has the form of a pad corresponding to the solder bump; or the first alignment solder part and the second alignment solder part are both in the form of soldering bumps.

In some embodiments, the solder bumps are made of solder and the alignment solder joints are formed by melting the solder.

In some embodiments, substantially aligning the first alignment solder part with a corresponding second alignment solder part comprises: bringing the first and corresponding second alignment solder parts into contact with each other. In some embodiments, orthographic projections of centers of the first and corresponding second alignment solder parts in a plane in which the interconnect board lies are allowed to deviate.

In some embodiments, the perimeters of the first alignment solder of the interconnect board are each pre-formed with a solder well.

In some embodiments, further comprising dicing the interconnect board to obtain a plurality of semiconductor assemblies. In some embodiments, any semiconductor assembly corresponds to at least one semiconductor device.

In some embodiments, the interconnect board is cut by cutting off at least one alignment solder joint.

In some embodiments, the at least one semiconductor device is pressed with a pressing plate toward the interconnect board.

In some embodiments, applying pressure to the at least one semiconductor device toward the interconnect board while the alignment solder bumps are melted or partially melted to cause the first connection terminals and the corresponding second connection terminals to be bonded into interconnection bonds via thermocompression bonding, includes: after the alignment solder joints are solidified or substantially solidified, the soldering process is again used to melt or partially melt the alignment solder joints and then to press the at least one semiconductor device towards the interconnect board.

In some embodiments, applying pressure to the at least one semiconductor device toward the interconnect board while the alignment solder bumps are melted or partially melted to cause the first connection terminals and the corresponding second connection terminals to be bonded into interconnection bonds via thermocompression bonding, includes: after the alignment solder joints in the molten or partially molten state is formed, the at least one semiconductor device is pressed toward the interconnect board while maintaining the alignment solder joints in the molten or partially molten state.

In some embodiments, referring to FIG. 1d, the present application further provides a semiconductor assembly packaging method 4010, comprising steps 4000-4003, as described below.

Step 4000—providing a first semiconductor device and at least one second semiconductor device. In some embodiments, a plurality of first connection terminals and a plurality of first alignment solder parts are formed on an active surface of the first semiconductor device, a plurality of second connection terminals and a plurality of second alignment solder parts are formed on an active surface of the at least one second semiconductor device, the first connection terminals and the second connection terminals are in one-to-one correspondence, the first alignment solder parts and the second alignment solder parts are in one-to-one correspondence, and the height sum of any first connection terminal and corresponding second connection terminal is smaller than the height sum of any first alignment solder part and corresponding second alignment solder part.

Step 4001—placing the at least one second semiconductor device on the first semiconductor device such that the first alignment solder part is substantially (or approximately) aligned with a corresponding second alignment solder part.

Step 4002—bonding the first alignment solder part and the corresponding second alignment solder part to each other to form an alignment solder joint in a molten or partially molten state using a bonding process to align the first semiconductor device precisely or more precisely and the at least one second semiconductor device, leaving a space between the first connection terminals and the corresponding second connection terminals.

Step 4003—applying pressure to the at least one second semiconductor device towards the first semiconductor device while the alignment solder joints are melted or partially melted, so that the first connection terminals and the corresponding second connection terminals are bonded into interconnection bonds through thermocompression bonding.

The method 4010 differs from the method 1010 shown in FIG. 1a in that: the lower interconnect board is replaced by a first semiconductor device, i.e. one or more second semiconductor devices are soldered on the first semiconductor device, and the interconnection bonds are formed by thermocompression bonding. Thereby enabling direct interconnection of the second semiconductor device with the first semiconductor device. The related technical details can refer to the related description of the method shown in FIG. 1a, and are not described herein again.

In some embodiments, either one of the first and second alignment solder parts has the form of a solder bump and the other has the form of a pad corresponding to the solder bump; or the first alignment solder part and the second alignment solder part are both in the form of soldering bumps.

In some embodiments, the solder bumps are made of solder and the alignment solder joints are formed by melting the solder.

In some embodiments, substantially aligning the first alignment solder part with a corresponding second alignment solder part comprises: bringing the first and corresponding second alignment solder parts into contact with each other. In some embodiments, an orthographic projection of centers of the first and corresponding second alignment solder parts on a plane in which an active surface of the first semiconductor device is located allows for deviation.

In some embodiments, the at least one second semiconductor device is pressed with a pressing plate toward the first semiconductor device.

In some embodiments, applying pressure to the at least one second semiconductor device toward the first semiconductor device while the alignment solder joints are melted or partially melted to cause each first connection terminal and the corresponding second connection terminal to be bonded into an interconnection bond through thermocompression bonding, includes: after the alignment solder joints are solidified or substantially solidified, the soldering process is again used to melt or partially melt the alignment solder joints, and then the at least one second semiconductor device is pressed towards the first semiconductor device.

In some embodiments, applying pressure to the at least one second semiconductor device toward the first semiconductor device while the alignment solder joints are melted or partially melted to cause the first connection terminal and the corresponding second connection terminal to be bonded into an interconnection bond through thermocompression bonding, includes: after the alignment solder joints in the molten or partially molten state is formed, the at least one second semiconductor device is pressed toward the first semiconductor device while maintaining the alignment solder joints in the molten or partially molten state.

Generally, in the scenario of fixing the second semiconductor device to the first semiconductor device, the semiconductor assembly can be obtained without performing a dicing process after the fixing and interconnection of the two devices are completed.

Embodiments of the present application also provide a semiconductor device manufactured by the aforementioned method.

Embodiments of the present application also provide an electronic device, which includes the aforementioned semiconductor component.

The embodiments in the present application are described in a progressive manner, and the same and similar parts among the embodiments can be referred to each other, and each embodiment focuses on the differences from the other embodiments.

The protective scope of the present application is not limited to the above-described embodiments, and it is apparent that various modifications and variations can be made to the present application by those skilled in the art without departing from the scope and spirit of the present application. It is intended that the present application also include such modifications and variations as come within the scope of the appended claims and their equivalents.

What is claimed is:

1. A method of packaging a semiconductor assembly, comprising:
providing an interconnect board and at least one semiconductor device, wherein the interconnect board has formed on a surface thereof first connection terminals and first alignment solder parts, wherein the at least one semiconductor device has formed on an active side thereof second connection terminals respectively corresponding to the plurality of first connection terminals, and second alignment solder parts respectively corresponding to the first alignment solder parts, and wherein a sum of a height of any first connection terminal and that of a corresponding second connection terminal is smaller than a sum of a height of any first alignment solder part and that of a corresponding second alignment solder part;
placing the at least one semiconductor device on the interconnect board such that the first alignment solder parts are respectively and at least approximately aligned with the second alignment solder parts;
bonding the first alignment solder parts and the corresponding second alignment solder parts to form alignment solder joints in a molten or partially molten state to further align the at least one semiconductor device to the interconnect board, leaving a gap between the first connection terminals and the corresponding second connection terminals; and
applying pressure to the at least one semiconductor device and/or the interconnect board while the alignment solder joints are in a molten or partially molten state, whereby the first connection terminals are bonded to the corresponding second connection terminals.

2. The method of claim 1, wherein
the first alignment parts are first solder bumps, and the second alignment solder parts are solder pads corresponding to the first solder bump; or the second alignment parts are second solder bumps, and the first alignment solder parts are solder pads corresponding to the second solder bump; or the first alignment solder parts and the second alignment solder parts are both solder bumps;
the first connection terminals are third solder bumps, and the second connection terminals parts are solder pads corresponding to the third solder bump; or the second connection terminals are fourth solder bumps, and the first connection terminals are solder pads corresponding to the fourth solder bump; or the first connection terminals and the second connection terminals are both solder bumps;
each solder bump is made of solder;
the alignment solder joints are formed by melting the solder; and
the first connection terminals are respectively bonded to the corresponding second connection terminals in a molten or partially molten state by melting the solder.

3. The method of claim 1, wherein placing the at least one semiconductor device on the interconnect board such that the first alignment solder parts are at least approximately and respectively aligned with the second alignment solder parts comprises: bringing each of the first solder parts and a corresponding one of the second solder parts into contact with each other while allowing orthographic projection of a center of any of the first solder parts and to deviate from alignment with orthographic projection of a center of a corresponding second solder part.

4. The method of claim 1, wherein the interconnect board further includes a solder trap along a perimeter of each of the first alignment solder parts.

5. The method of claim 1, further comprising: dicing the interconnect board to obtain a plurality of semiconductor assemblies each corresponding to at least one semiconductor device.

6. The method of claim 5, wherein dicing the interconnect board includes cutting off at least one alignment solder joint.

7. The method of claim 1, wherein applying pressure to the at least one semiconductor device and/or the interconnect board comprises applying pressure to the at least one semiconductor device toward the interconnect board using a pressing plate.

8. The method of claim 1, further comprising, after bonding the first alignment solder parts and the corresponding second alignment solder parts to form alignment solder joints in a molten or partially molten state to further align the at least one semiconductor device to the interconnect board, and before applying pressure to the at least one semiconductor device and/or the interconnect board:
keeping the alignment solder joints, and the first connection terminal and/or the second connection terminal in a molten or partially molten state; or re-melting the alignment solder joints, and the first connection terminal and/or the second connection terminal into a molten or partially molten state.

9. The method of claim 8, wherein the first connection terminals are bonded to the corresponding second connection terminals while first connection terminals and the corresponding second connection terminals are in a molten or partially molten state.

10. The method of claim 9, further comprising releasing the pressure after the alignment solder joints are solidified or substantially solidified and the first connection terminals are firmly bonded to the corresponding second connection terminals.

11. The method of claim 8, wherein the first connection terminals are bonded to the corresponding second connection terminals by thermocompression bonding.

12. A method of packaging a semiconductor assembly, comprising:
providing a first semiconductor device and at least one second semiconductor device, wherein the first semiconductor device has formed on an active side thereof first connection terminals and first alignment solder parts, wherein the at least one second semiconductor device has formed on an active side thereof second connection terminals respectively corresponding to the plurality of first connection terminals, and second alignment solder parts respectively corresponding to the first alignment solder parts, and wherein a sum of a height of any first connection terminal and that of a corresponding second connection terminal is smaller than a sum of a height of any first alignment solder part and that of a corresponding second alignment solder part;
placing the at least one second semiconductor device on the first semiconductor device such that the first alignment solder parts are at least approximately and respectively aligned with the second alignment solder parts;
bonding the first alignment solder parts and the corresponding second alignment solder parts to form corresponding alignment solder joints in a molten or partially molten state to further align the at least one second semiconductor device to the first semiconductor device, leaving a gap between the first connection terminals and the corresponding second connection terminals; and
applying pressure to the at least one second semiconductor device and/or the first semiconductor device while the alignment solder joints are in a molten or partially molten state, whereby the first connection terminals are bonded to the corresponding second connection terminals.

13. The method of claim 12, wherein
the first alignment parts are first solder bumps, and the second alignment solder parts are solder pads corresponding to the first solder bump; or the second alignment parts are second solder bumps, and the first alignment solder parts are solder pads corresponding to the second solder bump; or the first alignment solder parts and the second alignment solder parts are both solder bumps; and
the first connection terminals are third solder bumps, and the second connection terminals parts are solder pads corresponding to the third solder bump; or the second connection terminals are fourth solder bumps, and the first connection terminals are solder pads corresponding to the fourth solder bump; or the first connection terminals and the second connection terminals are both solder bumps.

14. The method of claim 13, wherein
each solder bump is made of solder;
the alignment solder joints are formed by melting the solder; and
the first connection terminals are respectively bonded to the corresponding second connection terminals in a molten or partially molten state by melting the solder.

15. The method of claim 12, wherein placing the at least one second semiconductor device on the first semiconductor device such that the first alignment solder parts are at least approximately and respectively aligned with the second alignment solder parts comprises:
bringing each of the first solder parts and a corresponding one of the second solder parts in contact with each other while allowing orthographic projection of a center of any of the first solder parts and to deviate from alignment with orthographic projection of a center of a corresponding second solder part.

16. The method of claim 12, wherein applying pressure to the at least one second semiconductor device and/or the first semiconductor device comprises applying pressure to the at least one second semiconductor device toward the first semiconductor device using a pressing plate.

17. The method of claim 12, further comprising, after bonding the first alignment solder parts and the corresponding second alignment solder parts to form alignment solder joints in a molten or partially molten state to further align the at least one second semiconductor device to the first semiconductor device, and before applying pressure to the at least one second semiconductor device and/or the first semiconductor device:
keeping the alignment solder joints, and the first connection terminal and/or the second connection terminal in a molten or partially molten state; or
re-melting the alignment solder joints, and the first connection terminal and/or the second connection terminal into a molten or partially molten state.

18. The method of claim 17, wherein the first connection terminals are bonded to the corresponding second connection terminals while first connection terminals and the corresponding second connection terminals are in a molten or partially molten state.

19. The method of claim 18, further comprising releasing the pressure after the alignment solder joints are solidified or substantially solidified and the first connection terminals are firmly bonded to the corresponding second connection terminals.

20. The method of claim 17, wherein the first connection terminals are bonded to the corresponding second connection terminals by thermocompression bonding.
